(19) United States
(12) Patent Application Publication
(10) Pub. No.: US 2026/0033149 A1
(43) Pub. Date: Jan. 29, 2026

(54) DISPLAY PANEL, AND MANUFACTURING METHOD OF THE SAME

(71) Applicant: HKC CORPORATION LIMITED, SHENZHEN (CN)

(72) Inventors: Dongmei WEI, SHENZHEN (CN); Tien-Chun HUANG, SHENZHEN (CN); Chuan WU, SHENZHEN (CN); Zhonglin CAO, SHENZHEN (CN); Lidan YE, SHENZHEN (CN)

(73) Assignee: HKC CORPORATION LIMITED, SHENZHEN (CN)

(21) Appl. No.: 19/260,591

(22) Filed: Jul. 6, 2025

(30) Foreign Application Priority Data
Jul. 23, 2024 (CN) 202410994935.X

(51) Int. Cl. H10K 59/122; H10K 59/12; H10K 59/80; H10K 71/16; H10K 71/60

(52) U.S. Cl. CPC H10K 59/122; H10K 59/1201; H10K 59/80521; H10K 59/873; H10K 71/166; H10K 71/60

(57) ABSTRACT

A display panel and a manufacturing method of the same. The method includes: preparing a drive circuit backplate which includes a drive circuit layer; preparing a light-emitting unit substrate which includes a glass substrate; and connecting the light-emitting unit substrate to the drive circuit backplate. Pixel via holes and cathode via holes on the glass substrate. Light-emitting devices are arranged on the glass substrate; each light-emitting device includes an anode film layer, a light-emitting layer, and a cathode film layer sequentially stacked and further includes an anode conductive portion and a cathode conductive portion. When the light-emitting unit substrate is connected to the drive circuit backplate, the glass substrate is disposed on the drive circuit backplate, the anode conductive portion is connected to a portion of the drive circuit layer, and the cathode conductive portion is connected to another portion of the drive circuit layer.

### CROSS-REFERENCE TO RELATED APPLICATIONS

The present application claims priority of Chinese Patent Application No. 202410994935.X, filed on Jul. 23, 2024, the entire contents of which are hereby incorporated by reference in their entirety.

### TECHNICAL FIELD

The present disclosure relates to the field of optical display technologies, and in particular to a display panel and a manufacturing method of the same.

### BACKGROUND

A Silicon-based micro display is characterized by a monocrystalline silicon substrate with a Complementary Metal Oxide Semiconductor (CMOS)-driven circuit integrated into a backplate, which offers enhanced integration and predominantly adopts a top-emitting configuration. Current silicon-based micro displays encompass four primary forms: Digital Micromirror Devices (DMDs), Silicon-based Liquid Crystal Displays (SiLCDs), Silicon-based Organic Light-Emitting (SiOLED) devices, and Silicon-based Diode Light-Emitting (SiDLED) devices. Due to their compact dimensions, optical systems are typically required to achieve wide-field display effects, for enabling near-eye display applications.

Among these, Organic Light-Emitting Displays (OLEDs) exhibit the superior performance in AR/VR applications. Compared to conventional active-matrix organic light-emitting diodes (AMOLEDs) utilizing amorphous silicon, microcrystalline silicon, or low-temperature polycrystalline silicon thin-film transistors as backplates, single-crystal silicon backplates provide significantly higher carrier mobility. The above display devices are AMOLED display devices made using CMOS devices as drive units, integrating traditional external display chips into a silicon-based backplate. During fabrication, a pixel-patterned isolation layer is vapor-deposited on the silicon-based CMOS drive substrate, followed by sequential vapor-deposition of an anode film, light-emitting layer, and cathode film. Therefore, this may result in insufficient panel lightness and complex preparation processes.

### SUMMARY OF THE DISCLOSURE

The purpose of the present disclosure is to provide a display panel and a manufacturing method of the same.

A manufacturing method of a display panel, including:
preparing a drive circuit backplate; wherein the drive circuit backplate includes a drive circuit layer;
preparing a light-emitting unit substrate, including:
   defining pixel via holes and cathode via holes on a glass substrate, with the cathode via holes located outside the pixel via holes in a radial direction of the display panel; and
   forming a plurality of light-emitting devices on a side of the glass substrate; wherein each of the plurality of light-emitting devices includes an anode film layer, a light-emitting layer, and a cathode film layer formed sequentially from a side near the drive circuit backplate toward a side far from the drive circuit backplate; the anode film layer, the light-emitting layer, and the cathode film layer are disposed in a corresponding pixel via hole; on a side of the glass substrate away from the drive circuit backplate, the cathode film layer extends out of the corresponding pixel via hole and covers the glass substrate; each of the plurality of light-emitting devices further includes an anode conductive portion and a cathode conductive portion; the anode conductive portion is electrically connected to the anode film layer and extends toward the drive circuit layer; the cathode conductive portion is electrically connected to the cathode film layer, and the cathode conductive portion is disposed in a corresponding cathode via hole and extends toward the drive circuit layer; and
connecting the light-emitting unit substrate to the drive circuit backplate, with the glass substrate disposed on the drive circuit backplate, the anode conductive portion of each light-emitting device connected to a corresponding portion of the drive circuit layer, and the cathode conductive portion of each light-emitting device connected to another corresponding portion of the drive circuit layer.

A display panel, including:
a drive circuit backplate, including a drive circuit layer; and
a light-emitting unit carrier plate, including:
   a glass substrate, defining pixel via holes and cathode via holes; wherein the cathode via holes are located outside the pixel via holes in a radial direction of the display panel; and
   a plurality of light-emitting devices, disposed on a side of the glass substrate; wherein each of the plurality of light-emitting devices includes an anode film layer, a light-emitting layer, and a cathode film layer formed sequentially from a side near the drive circuit backplate toward a side far from the drive circuit backplate; the anode film layer, the light-emitting layer, and the cathode film layer are disposed in a corresponding pixel via hole; on a side of the glass substrate away from the drive circuit backplate, the cathode film layer extends out of the corresponding pixel via hole and covers the glass substrate; each of the plurality of light-emitting devices further includes an anode conductive portion and a cathode conductive portion; the anode conductive portion is electrically connected to the anode film layer and extends toward the drive circuit layer; the cathode conductive portion is electrically connected to the cathode film layer, and the cathode conductive portion is disposed in a corresponding cathode via hole and extends toward the drive circuit layer;
wherein in a case where the light-emitting unit substrate is connected to the drive circuit backplate, the glass substrate is disposed on the drive circuit backplate, the anode conductive portion of each light-emitting device is connected to a corresponding portion of the drive circuit layer, and the cathode conductive portion of each light-emitting device is connected to another corresponding portion of the drive circuit layer.

### BRIEF DESCRIPTION OF THE DRAWINGS

The accompanying drawings are incorporated into the specification and form an integral part thereof, illustrating embodiments of the present disclosure and, together with the specification, serving to explain the principles of the present disclosure. It will be apparent from the accompanying drawings that the embodiments described herein are merely some examples of the present disclosure, and that other drawings may be obtained by those skilled in the art without creative labor based on these drawings.

FIG. 1 is a flowchart of a manufacturing method of a display panel according to some embodiments of the present disclosure.

FIG. 2 is a flowchart of operation S200 in the manufacturing method as illustrated in FIG. 1.

FIG. 3 is a structural schematic view of a display panel according to some embodiments of the present disclosure.

FIG. 4 is a flowchart of operation S100 in the manufacturing method as illustrated in FIG. 1.

FIG. 5a is a structural schematic view of a first pixel via hole defined on a glass substrate according to some embodiments of the present disclosure.

FIG. 5b is a structural schematic view of a second pixel via hole defined on a glass substrate according to some embodiments of the present disclosure.

FIG. 5c is a structural schematic view of a third pixel via hole defined on a glass substrate according to some embodiments of the present disclosure.

FIG. 5d is a structural schematic view of a cathode via hole defined on a glass substrate according to some embodiments of the present disclosure.

FIG. 6 is a flowchart of operation S210 in the manufacturing method as illustrated in FIG. 1.

FIG. 7 is a flowchart of operation S220 in the manufacturing method as illustrated in FIG. 1.

FIG. 8a is a structural schematic view of a first light-emitting device deposited on a glass substrate according to some embodiments of the present disclosure.

FIG. 8b is a structural schematic view of a second light-emitting device deposited on a glass substrate according to some embodiments of the present disclosure.

FIG. 8c is a structural schematic view of a third light-emitting device deposited on a glass substrate according to some embodiments of the present disclosure.

FIG. 8d is a structural schematic view of a cathode film layer formed on a glass substrate according to some embodiments of the present disclosure.

### DETAILED DESCRIPTION

The exemplary embodiments will now be described in greater detail with reference to the accompanying drawings. However, the exemplary embodiments may be implemented in various forms and should not be limited to the examples described herein; rather, the provision of these embodiments is intended to make the present disclosure more comprehensive and complete and to convey the concept of the exemplary embodiments to those skilled in the art.

Furthermore, the features, structures, or characteristics described may be combined in any suitable manner in one or more embodiments. In the following description, many specific details are provided to give a thorough understanding of the embodiments of the present disclosure. However, those skilled in the art will realize that the technical solutions of the present disclosure may be practiced without one or more of the specific details, or that other methods, components, devices, steps, etc. may be used. In other cases, well-known methods, apparatuses, implementations, or operations are not shown or described in detail to avoid obscuring the various aspects of the present disclosure.

The present disclosure is further described below with reference to the accompanying drawings and specific embodiments. It should be noted that the technical features described in the various embodiments of the present disclosure may be combined with each other as long as they do not conflict with each other. The embodiments described below with reference to the accompanying drawings are exemplary and are intended to explain the present disclosure and should not be understood as limiting the present disclosure.

It should be noted that “multiple” as used herein refers to two or more. “And/or” describes a relationship between associated objects, indicating that three relationships may exist. For example, “A and/or B” may indicate: A exists alone, A and B exist together, or B exists alone. The character “/” generally indicates that the associated objects before and after it are in an “or” relationship.

A Silicon-based micro display is characterized by a monocrystalline silicon substrate with a Complementary Metal Oxide Semiconductor (CMOS)-driven circuit integrated into a backplate, which offers enhanced integration and predominantly adopts a top-emitting configuration. Current silicon-based micro displays encompass four primary forms: Digital Micromirror Devices (DMDs), Silicon-based Liquid Crystal Displays (SiLCDs), Silicon-based Organic Light-Emitting (SiOLED) devices, and Silicon-based Diode Light-Emitting (SiDLED) devices. Due to their compact dimensions, optical systems are typically required to achieve wide-field display effects, for enabling near-eye display applications.

Among these, Organic Light-Emitting Displays (OLEDs) exhibit the superior performance in AR/VR applications. Compared to conventional active-matrix organic light-emitting diodes (AMOLEDs) utilizing amorphous silicon, microcrystalline silicon, or low-temperature polycrystalline silicon thin-film transistors as backplates, single-crystal silicon backplates provide significantly higher carrier mobility. The above display devices are AMOLED display devices made using CMOS devices as drive units, integrating traditional external display chips into a silicon-based backplate. During fabrication, a pixel-patterned isolation layer is vapor-deposited on the silicon-based CMOS drive substrate, followed by sequential vapor-deposition of an anode film, light-emitting layer, and cathode film. Therefore, this may result in insufficient panel lightness and complex preparation processes.

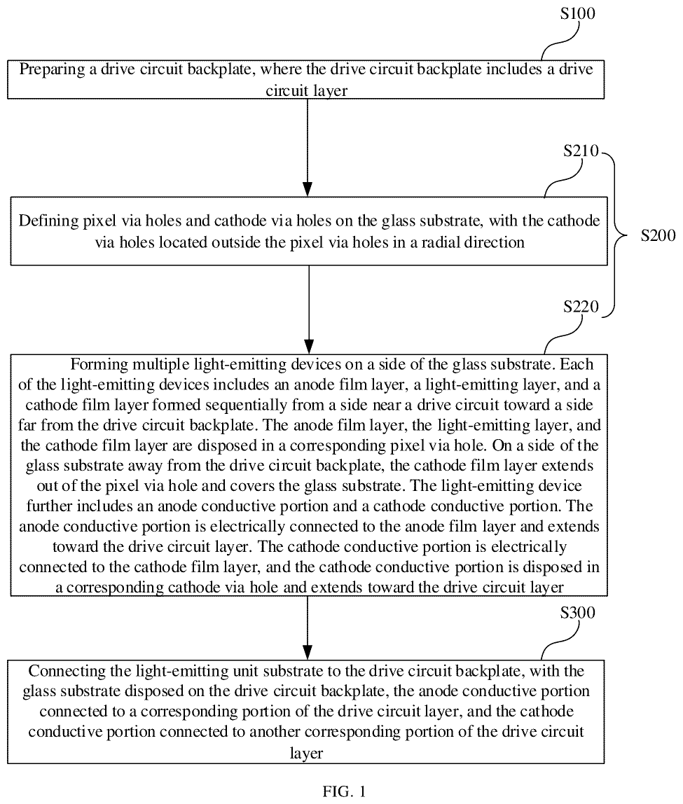

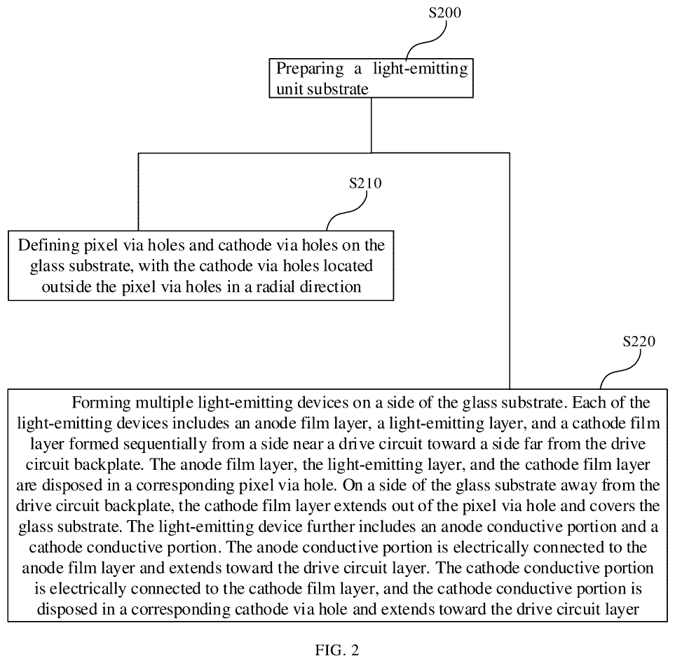

To address the above technical issues, referring to FIGS. 1 and 2, the present disclosure provides a manufacturing method of a display panel, specifically including operations S100 to S300 at blocks as illustrated herein.

At block S100: Preparing a drive circuit backplate 10, where the drive circuit backplate 10 includes a drive circuit layer 11.

The drive circuit layer 11 is fabricated using a complementary metal oxide semiconductor (CMOS) process and is configured to supply power to a light-emitting unit substrate 20.

At block S200: Preparing a light-emitting unit substrate 20. Referring to FIG. 2, the preparation method of the light-emitting unit substrate 20 includes operations S210 to S220 at blocks as illustrated herein.

At block S210: Defining pixel via holes 211 and cathode via holes 212 on the glass substrate 21, with the cathode via holes 212 located outside the pixel via holes 211 in a radial direction X1.

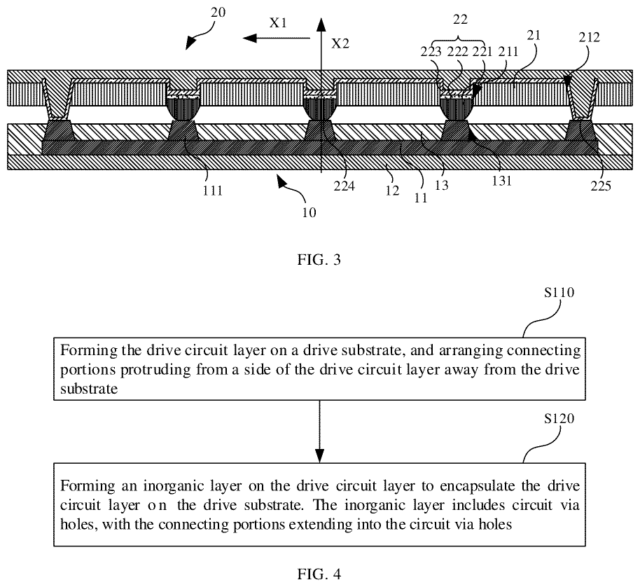

As shown in FIG. 3, the glass substrate 21 may improve the light transmittance of the display panel and increase the brightness of the display panel. The holes on the glass substrate 21 are prepared using processes such as laser drilling through a mask plate. The holes on the glass substrate 21 include pixel via holes 211 and cathode via holes 212, which are configured to further form light-emitting devices 22, anode conductive portions 224, and cathode conductive portions 225 in subsequent preparation processes. The hole diameter and shape of the pixel via holes 211 and cathode via holes 212 are selected based on actual conditions.

The pixel via holes 211 are arranged in an array on the glass substrate 21. The radial direction X1 is a direction along an axis line within a radial plane, where the axis line is configured as an axis line of the pixel via holes 211 arranged in the array.

At block S220: Forming multiple light-emitting devices 22 on a side of the glass substrate 21. Each of the light-emitting devices 22 includes an anode film layer 221, a light-emitting layer 222, and a cathode film layer 223 formed sequentially from a side near a drive circuit toward a side far from the drive circuit backplate 10. The anode film layer 221, the light-emitting layer 222, and the cathode film layer 223 are disposed in a corresponding pixel via hole 211. On a side of the glass substrate 21 away from the drive circuit backplate 10, the cathode film layer 223 extends out of the pixel via hole 211 and covers the glass substrate 21. The light-emitting device 22 further includes an anode conductive portion 224 and a cathode conductive portion 225. The anode conductive portion 224 is electrically connected to the anode film layer 221 and extends toward the drive circuit layer 11. The cathode conductive portion 225 is electrically connected to the cathode film layer 223, and the cathode conductive portion 225 is disposed in a corresponding cathode via hole 212 and extends toward the drive circuit layer 11.

As shown in FIG. 3, by supplying power to the anode film layer 221 and the cathode film layer 223 through the drive circuit layer 11, the light-emitting layer 222 emits light to achieve image display. On the side of the glass substrate 21 away from the drive circuit backplate 10, the cathode film layer 223 extends out of the pixel via holes 211 and covers the glass substrate 21, forming a cathode film layer 223 with an integral film layer structure on the side of the glass substrate 21 away from the drive circuit backplate 10.

The multiple light-emitting devices 22 include multiple light-emitting devices 22 that emit red light, multiple light-emitting devices 22 that emit green light, and multiple light-emitting devices 22 that emit blue light. This enables the realization of color display of the display panel, where the side of the light-emitting unit carrier plate 20 away from the drive substrate 12 is a light-emitting side.

The anode film layer 221, the light-emitting layer 222, and the cathode film layer 223 are formed on the glass substrate 21 via processes such as vapor deposition. Depending on actual situations, additional processes such as cleaning, drying, and etching may be required. Compared to the related art where the anode film layer, light-emitting layer, and cathode film layer of the light-emitting device are formed after an isolation structure is arranged on the glass substrate, since the anode film layer 221, light-emitting layer 222, and cathode film layer 223 are disposed within the pixel via hole 211 of the glass substrate 21, the process steps are reduced, further decreasing the thickness of the display panel, thereby enhancing the portability of the display panel.

The anode film layers 221 and light-emitting layers 222 of multiple light-emitting devices 22 of the same color may be simultaneously vapor-deposited. After the anode film layers 221 and light-emitting layers 222 of the three-color light-emitting devices 22 are vapor-deposited, the cathode film layer 223 is deposited, forming the cathode film layer 223 simultaneously on the pixel via holes 211 and the glass substrate 21 to achieve the integral film layer structure. Compared to a design where a separate cathode film layer 223 is provided for each light-emitting device 22, this configuration may reduce the number of cathode circuits in the drive circuit layer 11, simplify the design, and reduce the thickness of the drive circuit backplate 10, thereby enhancing the lightweight design of the display panel.

The anode conductive portion 224 is configured to conduct electrical signals between the anode film layer 221 and the drive circuit layer 11, while the cathode conductive portion 225 is configured to conduct electrical signals between the cathode film layer 223 and the drive circuit layer 11. Since the cathode film layer 223 is located on the side of the glass substrate 21 away from the drive circuit backplate 10, the cathode via holes 212 are required to be defined on the glass substrate 21 to allow the cathode conductive portion 225 to extend toward the drive circuit backplate 10. The lengths of the anode conductive portion 224 and the cathode conductive portion 225 extending toward the drive circuit backplate 10 are determined based on actual conditions to ensure good electrical connection with the drive circuit layer 11.

At block S300: Connecting the light-emitting unit substrate 20 to the drive circuit backplate 10, with the glass substrate 21 disposed on the drive circuit backplate 10, the anode conductive portion 224 connected to a corresponding portion of the drive circuit layer 11, and the cathode conductive portion 225 connected to another corresponding portion of the drive circuit layer 11.

As shown in FIG. 3, the anode conductive portion 224 is connected to a portion of the drive circuit layer 11, and the cathode conductive portion 225 is connected to another portion of the drive circuit layer 11, thereby achieving electrical connection between the light-emitting unit substrate 20 and the drive circuit backplate 10. The drive circuit layer 11 includes an anode circuit for driving the anode film layer 221 and a cathode circuit for driving the cathode film layer 223, to provide electrical signals to the anode film layer 221 and the cathode film layer 223, respectively.

In the embodiments, the drive circuit layer 11 is configured to supply power to the light-emitting unit substrate 20. The pixel via holes 211 are configured to form the anode film layer 221, the light-emitting layer 222, and the cathode film layer 223. Each pixel via hole 211 corresponds to a light-emitting device 22, where the light-emitting layer 222 is driven by the anode film layer 221 and the cathode film layer 223 to emit light. On the side of the glass substrate 21 away from the drive circuit backplate 10, the cathode film layer 223 extends out of the pixel via hole 211 and covers the glass substrate 21, enabling simultaneous power supply to the light-emitting layers 222 in multiple pixel via holes 211 through the cathode film layer 223. The light-emitting device 22 further includes an anode conductive portion 224 and a cathode conductive portion 225. The anode conductive portion 224 is electrically connected to the anode film layer 221 and extends toward the drive circuit layer 11. The cathode conductive portion 225 is electrically connected to the cathode film layer 223 and is disposed within the cathode via hole 212, extending toward the drive circuit layer 11. When the light-emitting unit substrate 20 and the drive circuit backplate 10 are connected, the glass substrate 21 is disposed on the drive circuit backplate 10, the anode conductive portion 224 is connected to a portion of the drive circuit layer 11, and the cathode conductive portion 225 is connected to another portion of the drive circuit layer 11, thereby achieving electrical connection between the light-emitting device 22 and the drive circuit layer 11, and thus enabling the drive circuit layer 11 to supply power to the light-emitting device 22. Compared to the related art, where an isolation structure is formed on the glass substrate to form the anode film layer, the light-emitting layer, and the cathode film layer of the light-emitting device, the anode film layer 221, the light-emitting layer 222, and the cathode film layer 223 are disposed in the pixel via hole 211 of the glass substrate 21, thereby simplifying the manufacturing process, further reducing the thickness of the display panel, and thus enhancing the portability of the display panel.

Referring to FIG. 4, the preparing a drive circuit backplate 10 includes operations S110 and S120 at blocks illustrated herein.

At block S110: Forming the drive circuit layer 11 on a drive substrate 12, and arranging connecting portions 111 protruding from a side of the drive circuit layer 11 away from the drive substrate 12.

The drive substrate 12 may be configured to be a silicon-based substrate, and the drive circuit layer 11 includes multiple active organic light-emitting diode display devices made using CMOS devices as drive units. The silicon-based substrate and the drive circuit layer 11 may be designed according to actual conditions.

The connecting portions 111 include a connecting portion 111 for connection to the cathode conductive portion 225 and a connecting portion 111 for connection to the anode film layer 221. The connecting portion 111 corresponding to the cathode conductive portion 225 is arranged facing the cathode conductive portion 225, and the connecting portion 111 corresponding to the anode film layer 221 is arranged facing the anode film layer 221. The connecting portion 111 may be formed on the drive circuit layer 11 through processes such as welding or etching. The specific process method for preparing the connecting portions 111 is not limited herein.

At block S120: Forming an inorganic layer 13 on the drive circuit layer 11 to encapsulate the drive circuit layer 11 on the drive substrate 12. The inorganic layer 13 includes circuit via holes 131, with the connecting portions 111 extending into the circuit via holes 131.

The inorganic layer 13 may be configured to be a SiO₂ layer to provide protective coverage after encapsulating the drive circuit layer 11. After an inorganic material is vapor-deposited on the drive circuit layer 11 to define the circuit via holes 131, the connecting portions 111 extend into the circuit via holes 131 and are in contact with the anode conductive portion 224 and the cathode conductive portion 225.

In the embodiments, such a design achieves electrical connection by having the connecting portions 111 in contact with the anode conductive portion 224 and the cathode conductive portion 225, which may reduce the risk of water vapor and dust entering the drive circuit backplate 10, thereby providing good protection for the drive circuit backplate 10.

In some embodiments, as shown in FIG. 3, in an axial direction X2, the height of the connecting portion 111 is greater than the height of the circuit via hole 131, the height of the anode conductive portion 224 is less than the height of the pixel via hole 211, and the height of the cathode conductive portion 225 is less than the height of the cathode via hole 212. When the connecting portions 111 are connected to the anode conductive portion 224 and the cathode conductive portion 224, the connecting portions 111 can extend into the pixel via hole 211 and the cathode via hole 212. As a result, based on the connecting portions 111 being in contact with the anode conductive portion 224 and the anode conductive portion 224, the connecting portions 111 extend into the pixel via hole 211 and the cathode via hole 212 to serve as positioning elements, thereby improving the alignment accuracy between the drive circuit backplate 10 and the light-emitting unit substrate 20.

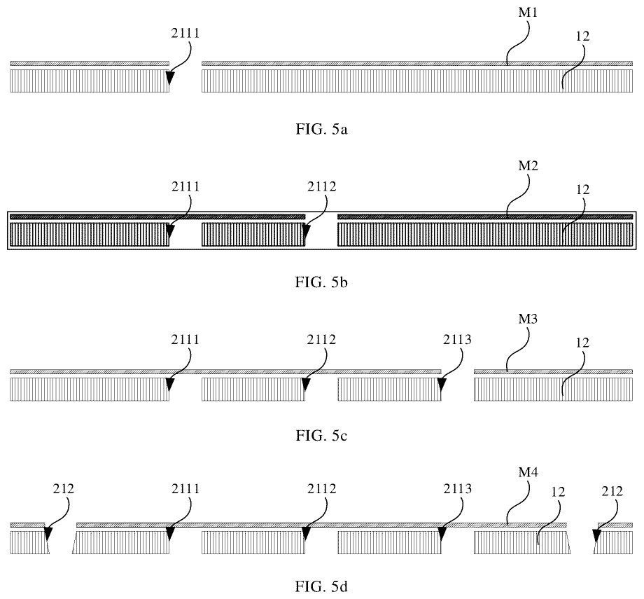

In some embodiments, as shown in FIGS. 5a to 5d, the pixel via holes 211 include a first pixel via hole 2111, a second pixel via hole 2112, and a third pixel via hole 2113. The first pixel via hole 2111, the second pixel via hole 2112, and the third pixel via hole 2113 are configured to accommodate light-emitting devices 22 of different colors, while the cathode via hole 212 is configured to accommodate the cathode conductive portion 225. Specifically, the first pixel via hole 2111 is configured to arrange a corresponding one of the multiple light-emitting devices 22 that emit red light, the second pixel via hole 2112 is configured to arrange a corresponding one of the multiple light-emitting devices 22 that emit green light, and the third pixel via hole 2113 is configured to arrange a corresponding one of the multiple light-emitting devices 22 that emit blue light. The first pixel via hole 2111, the second pixel via hole 2112, and the third pixel via hole 2113 may be distributed in any manner, and no specific arrangement of the three is specified here.

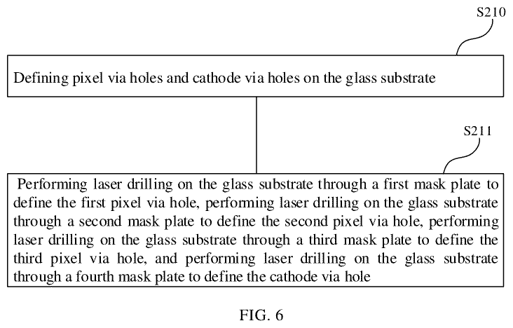

In some embodiments, as shown in FIG. 6, the defining pixel via holes 211 and cathode via holes 212 on the glass substrate 21 include operations at blocks illustrated herein.

At block S211: Performing laser drilling on the glass substrate 21 through a first mask plate M1 to define the first pixel via hole 2111, performing laser drilling on the glass substrate 21 through a second mask plate M2 to define the second pixel via hole 2112, performing laser drilling on the glass substrate 21 through a third mask plate M3 to define the third pixel via hole 2113, and performing laser drilling on the glass substrate 21 through a fourth mask plate M4 to define the cathode via hole 212.

As shown in FIGS. 5a to 5d, the first mask plate M1, the second mask plate M2, and the third mask plate M3 are different mask plates. The first mask plate M1 serves as a template during laser drilling of the first pixel via hole 2111, the second mask plate M2 serves as a template during laser drilling of the second pixel via hole 2112, and the third mask plate M3 serves as a template during laser drilling of the third pixel via hole 2113. The fourth mask plate M4 serves as a template during laser drilling of the cathode via hole 212. For example, when laser drilling is performed on the glass substrate 21 to define the first pixel via hole 2111, the first mask plate M1 is placed on the glass substrate 21. After the laser is activated, the laser beam passes through the openings in the first mask plate M1 and acts on the glass substrate 21, to define the first pixel via holes 2111. The process is repeated to prepare the second pixel via hole 2112, the third pixel via hole 2113, and the cathode via hole 212, thereby defining the second pixel via hole 2112, the third pixel via hole 2113, and the cathode via hole 212, respectively.

In other embodiments, patterns of the first pixel via hole 2111, the second pixel via hole 2112, and the third pixel via hole 2113 are formed on the glass substrate 21 by exposure and development through the first mask plate M1, the second mask plate M2, and the third mask plate M3, respectively. The pattern of the cathode via hole 212 is formed on the glass substrate 21 by exposure and development through the fourth mask plate M4. The patterns of the first pixel via hole 2111, the second pixel via hole 2112, the third pixel via hole 2113, and the cathode via hole 212 are etched to define the first pixel via hole 2111, the second pixel via hole 2112, the third pixel via hole 2113, and the cathode via hole 212.

Specifically, the first mask plate M1, the second mask plate M2, and the third mask plate M3 are different mask plates. The first mask plate M1 is configured for exposure and development to form the pattern of the first pixel via hole 2111, the second mask plate M2 is configured for exposure and development to form the pattern of the second pixel via hole 2112, and the third mask plate M3 is configured for exposure and development to form the pattern of the third pixel via hole 2113. First, the pattern of the first pixel via hole 2111 is formed on the glass substrate 21 using the first mask plate M1. The first mask plate M1 is replaced with the second mask plate M2 to form the pattern of the second pixel via hole 2112. The second mask plate M2 is then replaced with the third mask plate M3 to form the pattern of the third pixel via hole 2113. The third mask plate M3 is then replaced with the fourth mask plate M4 to form the pattern of the cathode via hole 212. In the radial direction X1, the pattern of the cathode via hole 212 on the third mask plate M3 is located outside the patterns of the first pixel via hole 2111, the second pixel via hole 2112, and the third pixel via hole 2113. Etching is performed based on the patterns of the first pixel via hole 2111, the second pixel via hole 2112, the third pixel via hole 2113, and the cathode via hole 212. The etching process is not specifically defined herein. Further, additional processes such as applying photoresist, cleaning, and drying may be required depending on actual situations.

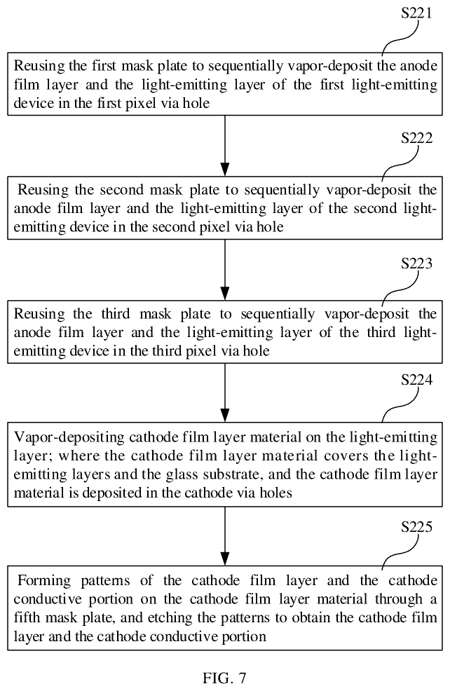

Referring to FIG. 7, the Forming multiple light-emitting devices 22 on a side of the glass substrate 21 may specifically include operations S221 to S223 at blocks illustrated herein.

At block S221: Reusing the first mask plate M1 to sequentially vapor-deposit the anode film layer 221 and the light-emitting layer 222 of the first light-emitting device 22 in the first pixel via hole 2111.

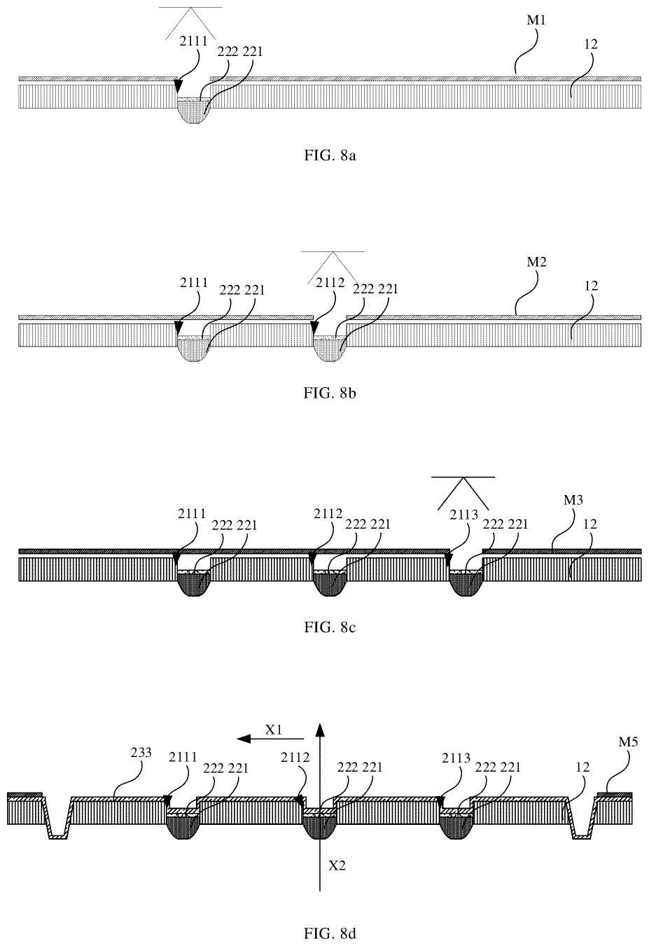

As shown in FIG. 8a, the reused first mask plate M1 can block the second pixel via holes 2112 and third pixel via holes 2113, while exposing multiple first pixel via holes 2111, thereby enabling the vapor-deposition of anode film layers 221 and light-emitting layers 222 of first light-emitting devices 22 of the same color in the multiple first pixel via holes 2111.

The anode film layer 221 and the anode conductive portion 224 may be an integrated structure. After the anode film layer 221 is formed by vapor deposition on a side of the glass substrate 21, the anode conductive portion 224 is vapor-deposited on an opposite side of the glass substrate 21, thereby forming the anode conductive portion 224 and the anode film layer 221 as an integrated structure. In this case, the anode conductive portion 224 and the anode film layer 221 are made of the same material.

The anode film layer 221 and the anode conductive portion 224 may be separate structures. After the anode film layer 221 is formed by vapor deposition on a side of the glass substrate 21, the anode conductive portion 224 is vapor-deposited on an opposite side of the glass substrate 21, with the anode conductive portion 224 and the anode film layer 221 in contact. In this case, the anode conductive portion 224 and the anode film layer 221 are made of different materials.

At block S222: Reusing the second mask plate M2 to sequentially vapor-deposit the anode film layer 221 and the light-emitting layer 222 of the second light-emitting device 22 in the second pixel via hole 2112.

As shown in FIG. 8b, the reused second mask plate M2 can block the first pixel via holes 2111 and the third pixel via holes 2113, while exposing multiple second pixel via holes 2112, thereby enabling the vapor-deposition of the anode film layers 221 and the light-emitting layers 222 of the second light-emitting devices 22 of the same color within the multiple second pixel via holes 2112.

At block S223: Reusing the third mask plate M3 to sequentially vapor-deposit the anode film layer 221 and the light-emitting layer 222 of the third light-emitting device 22 in the third pixel via hole 2113.

As shown in FIG. 8c, the reused third mask plate M3 can block the first pixel via holes 2111 and the second pixel via holes 2112, while exposing multiple third pixel via holes 2113, thereby enabling the vapor-deposition of the anode film layers 221 and the light-emitting layers 222 of the third light-emitting devices 22 of the same color in the multiple third pixel via holes 2113.

In the embodiments, reusing the first mask plate M1, the second mask plate M2, and the third mask plate M3 reduces the number of mask plates, thereby lowering the manufacturing cost of the display panel.

Referring to FIG. 7, the forming multiple light-emitting devices 22 on a side of the glass substrate 21 further includes operations S224 to S225 at blocks illustrated herein.

At block S224: Vapor-depositing cathode film layer material on the light-emitting layer 222; where the cathode film layer material covers the light-emitting layers 222 and the glass substrate 21, and the cathode film layer material is deposited in the cathode via holes 212.

As shown in FIG. 8d, the cathode film layer material can be deposited in a single deposition step to simultaneously cover the light-emitting layers 222 and the glass substrate 21, forming the integral film layer structure. Since the cathode via holes 212 are defined on the glass substrate 21, the cathode film layer material is also disposed within the cathode via holes 212 during deposition, eliminating the need to separately form the cathode conductive portion 225, thereby reducing process steps, and thus reducing the manufacturing cost of the display panel.

At block S225: Forming patterns of the cathode film layer 223 and the cathode conductive portion 225 on the cathode film layer material through a fifth mask plate M5, and etching the patterns to obtain the cathode film layer 223 and the cathode conductive portion 225.

Referring to FIG. 8d, a schematic diagram showing the formation of the cathode film layer 223 and the cathode conductive portion 225 on the cathode film layer material is illustrated. In the radial direction X1, the cathode film layer 223 extends along both sides of the glass substrate 21 from a surface of the glass substrate 21 away from the drive circuit backplate 10, and extends in the axial direction X2 into the cathode via holes 212. In the radial direction X1, the cathode film layer 223 and the cathode conductive portion 225 are located on the radial plane of the glass substrate 21, facilitating encapsulation in subsequent processes to provide better protection for the light-emitting devices 22.

The present disclosure further provides a display panel, as shown in FIGS. 1 to 8d, including a drive circuit backplate 10 and a light-emitting unit carrier plate 20, where the drive circuit backplate 10 is configured to supply power to the light-emitting unit carrier plate 20, and the light-emitting unit carrier plate 20 is capable of emitting light to display images.

In some embodiments, the drive circuit backplate 10 includes a drive circuit layer 11, and the light-emitting unit carrier plate 20 includes a glass substrate 21 and multiple light-emitting devices 22. The glass substrate 21 defines pixel via holes 211 and cathode via holes 212, where the cathode via holes 212 are located outside the pixel via holes 211 in a radial direction X1. Each light-emitting device 22 includes an anode film layer 221, a light-emitting layer 222, and a cathode film layer 223 arranged in sequence from a side near the drive circuit to a side far from the drive circuit backplate 10. The anode film layer 221, the light-emitting layer 222, and the cathode film layer 223 are disposed in the pixel via hole 211. On a side of the glass substrate 21 away from the drive circuit backplate 10, the cathode film layer 22 3 extends out of the pixel via holes 211 and covers the glass substrate 21. The light-emitting device 22 further includes an anode conductive portion 224 and a cathode conductive portion 225. The anode conductive portion 224 is electrically connected to the anode film layer 221 and extends toward the drive circuit layer 11, while the cathode conductive portion 225 is electrically connected to the cathode film layer 223 and is disposed in the cathode via hole 212 while extending toward the drive circuit layer 11. When the light-emitting unit substrate 20 and the drive circuit backplate 10 are connected together, the glass substrate 21 is disposed on the drive circuit backplate 10, with the anode conductive portion 224 connected to a portion of the drive circuit layer 11 and the cathode conductive portion 225 connected to another portion of the drive circuit layer 11.

In the embodiments, the pixel via holes 211 are configured to form the anode film layer 221, the light-emitting layer 222, and the cathode film layer 223. Each pixel via hole 211 corresponds to a light-emitting device 22, and the light-emitting layer 222 is driven to emit light through the anode film layer 221 and the cathode film layer 223. On the side of the glass substrate 21 away from the drive circuit backplate 10, the cathode film layer 223 extends out of the pixel via hole 211 and covers the glass substrate 21, enabling simultaneous power supply to the light-emitting layers 222 in multiple pixel via holes 211 through the cathode film layer 223. The light-emitting device 22 further includes an anode conductive portion 224 and a cathode conductive portion 225. The anode conductive portion 224 is electrically connected to the anode film layer 221 and extends toward the drive circuit layer 11. The cathode conductive portion 225 is electrically connected to the cathode film layer 223 and is disposed within the cathode via hole 212, extending toward the drive circuit layer 11. When the light-emitting unit substrate 20 and the drive circuit backplate 10 are connected, the glass substrate 21 is disposed on the drive circuit backplate 10, the anode conductive portion 224 is connected to a portion of the drive circuit layer 11, and the cathode conductive portion 225 is connected to another portion of the drive circuit layer 11, thereby achieving electrical connection between the light-emitting device 22 and the drive circuit layer 11, and thus enabling the drive circuit layer 11 to supply power to the light-emitting device 22. Compared to the related art, where an isolation structure is formed on the glass substrate to form the anode film layer, the light-emitting layer, and the cathode film layer of the light-emitting device, the anode film layer 221, the light-emitting layer 222, and the cathode film layer 223 are disposed in the pixel via hole 211 of the glass substrate 21, thereby simplifying the manufacturing process, further reducing the thickness of the display panel, and thus enhancing the portability of the display panel.

In some embodiments, the drive circuit backplate 10 further includes a drive substrate 12, a drive circuit layer 11, and an inorganic layer 13. The drive circuit layer 11 is disposed on the drive substrate 12, and connecting portions 111 are arranged protruding from a side of the drive circuit layer 11 away from the drive substrate 12. The inorganic layer 13 is disposed on the drive circuit layer 11, for encapsulating the drive circuit layer 11 on the drive substrate 12. The inorganic layer 13 defines circuit via holes 131, and the connecting portions 111 extend into the circuit via holes 131. In this way, this design may achieve electrical connection by contacting the connecting portions 111 with the anode conductive portion 224 and the cathode conductive portion 225, and may further reduce the risk of moisture and dust entering the drive circuit backplate 10, thereby providing effective protection for the drive circuit backplate 10.

In some embodiments, the pixel via holes 211 include a first pixel via hole 2111, a second pixel via hole 2112, and a third pixel via hole 2113. The glass substrate 21 is laser-drilled using a first mask plate M1, a second mask plate M2, and a third mask plate M3 to form the first pixel via hole 2111, the second pixel via hole 2112, and the third pixel via hole 2113. When laser drilling is performed on the glass substrate 21 to form the first pixel via hole 2111, the first mask plate M1 is placed on the glass substrate 21, and after the laser is activated, the laser beam passes through the openings in the first mask plate M1 and acts on the glass substrate 21, to define the first pixel via holes 2111. The process is repeated to define the second pixel via hole 2112, the third pixel via hole 2113, and the cathode via hole 212, thereby forming the second pixel via hole 2112, the third pixel via hole 2113, and the cathode via hole 212, respectively.

In some embodiments, the light-emitting devices 22 include first light-emitting devices 22, second light-emitting devices 22, and third light-emitting devices 22 of different colors. The first mask plate M1 is reused to sequentially deposit the anode film layer 221 and the light-emitting layer 222 of the first light-emitting device 22 in the first pixel via hole 2111. The second mask plate M2 is reused to sequentially deposit the anode film layer 222 and the light-emitting layer 222 of the second light-emitting device 22 in the second pixel via hole 2112. The third mask plate M3 is reused to sequentially deposit the anode film layer 221 and the light-emitting layer 222 of the third light-emitting device 22 in the third pixel via hole 2113. A cathode film layer material is deposited on the light-emitting layer 222, the cathode film layer material covers the light-emitting layer 222 and the glass substrate 21, and the cathode film layer material is deposited in the cathode via hole 212. Using the fifth mask plate M5, patterns of the cathode film layer 223 and the cathode conductive portion 225 are formed on the cathode film layer material, and the patterns are etched to obtain the cathode film layer 223 and the cathode conductive portion 225. In this way, by reusing the first mask plate M1, the second mask plate M2, and the third mask plate M3, the number of mask plates may be reduced, thereby lowering the manufacturing cost of the display panel.

In the display panel of the present disclosure, compared to the related art where the anode film layer, light-emitting layer, and cathode film layer are formed after an isolation structure is provided on the glass substrate, since the anode film layer 221, light-emitting layer 222, and cathode film layer 223 are disposed in the pixel via holes 211 of the glass substrate 21, the process steps are simplified, further reducing the thickness of the display panel and thereby enhancing its portability. By contacting the connecting portion 111 with the anode conductive portion 224 and the cathode conductive portion 225, electrical connection is achieved. This may further reduce the risk of moisture and dust entering the drive circuit backplate 10, thereby providing effective protection for the drive circuit backplate 10.

In the present disclosure, unless otherwise explicitly specified or limited, terms such as “arranged with,” “connected,” etc., should be interpreted broadly. For example, they may refer to fixed connections, removable connections, or integral structures; mechanical connections or electrical connections; direct connections or indirect connections via intermediate media; or internal communication between two components or an interactive relationship between two components. For those skilled in the art, the specific meaning of the above terms herein may be understood based on the specific circumstances.

In the description of this specification, the terms “some embodiments” and the like refer to at least one embodiment of the present disclosure that includes the specific features, structures, materials, or characteristics described in the embodiment. In this specification, the illustrative expressions of the above terms are not necessarily directed to the same embodiment or example. Furthermore, the specific features, structures, materials, or characteristics described may be combined in any one or more embodiments or examples in an appropriate manner. Additionally, without being mutually contradictory, those skilled in the art may combine and integrate the different embodiments or examples described in this specification, as well as the features of different embodiments or examples.

Although embodiments of the present disclosure have been shown and described above, it should be understood that the above embodiments are exemplary and not intended to limit the present disclosure. Those skilled in the art may make changes, modifications, replacements, and variations to the above embodiments within the scope of the present disclosure. Therefore, any changes or modifications made in accordance with the claims and description of the present disclosure should be considered within the scope of the present disclosure.

1. A manufacturing method of a display panel, comprising:
preparing a drive circuit backplate; wherein the drive circuit backplate comprises a drive circuit layer;
preparing a light-emitting unit substrate, comprising:
defining pixel via holes and cathode via holes on a glass substrate, with the cathode via holes located outside the pixel via holes in a radial direction of the display panel; and
forming a plurality of light-emitting devices on a side of the glass substrate; wherein each of the plurality of light-emitting devices comprises an anode film layer, a light-emitting layer, and a cathode film layer formed sequentially from a side near the drive circuit backplate toward a side far from the drive circuit backplate; the anode film layer, the light-emitting layer, and the cathode film layer are disposed in a corresponding pixel via hole; on a side of the glass substrate away from the drive circuit backplate, the cathode film layer extends out of the corresponding pixel via hole and covers the glass substrate; each of the plurality of light-emitting devices further comprises an anode conductive portion and a cathode conductive portion; the anode conductive portion is electrically connected to the anode film layer and extends toward the drive circuit layer; the cathode conductive portion is electrically connected to the cathode film layer, and the cathode conductive portion is disposed in a corresponding cathode via hole and extends toward the drive circuit layer; and
connecting the light-emitting unit substrate to the drive circuit backplate, with the glass substrate disposed on the drive circuit backplate, the anode conductive portion of each light-emitting device connected to a corresponding portion of the drive circuit layer, and the cathode conductive portion of each light-emitting device connected to another corresponding portion of the drive circuit layer.

2. The manufacturing method according to claim 1, wherein the preparing a drive circuit backplate comprises:
forming the drive circuit layer on a drive substrate, and arranging connecting portions protruding from a side of the drive circuit layer away from the drive substrate; and
forming an inorganic layer on the drive circuit layer to encapsulate the drive circuit layer on the drive substrate; wherein the inorganic layer comprises circuit via holes, with the connecting portions extending into the circuit via holes.

3. The manufacturing method according to claim 1, wherein the pixel via holes comprise a first pixel via hole, a second pixel via hole, and a third pixel via hole; the first pixel via hole, the second pixel via hole, and the third pixel via hole are configured to accommodate corresponding light-emitting devices of different colors, and the cathode via hole is configured to accommodate the cathode conductive portion of a corresponding light-emitting device.

4. The manufacturing method according to claim 3, wherein the defining pixel via holes and cathode via holes on the glass substrate comprises:
performing laser drilling on the glass substrate through a first mask plate to define the first pixel via hole, performing laser drilling on the glass substrate through a second mask plate to define the second pixel via hole, performing laser drilling on the glass substrate through a third mask plate to define the third pixel via hole, and performing laser drilling on the glass substrate through a fourth mask plate to define the cathode via hole.

5. The manufacturing method according to claim 4, wherein the light-emitting devices comprise a first light-emitting device, a second light-emitting device, and a third light-emitting device of different colors;
the forming a plurality of light-emitting devices on a side of the glass substrate comprises:
reusing the first mask plate to sequentially vapor-deposit the anode film layer and the light-emitting layer of the first light-emitting device in the first pixel via hole;
reusing the second mask plate to sequentially vapor-deposit the anode film layer and the light-emitting layer of the second light-emitting device in the second pixel via hole; and
reusing the third mask plate to sequentially vapor-deposit the anode film layer and the light-emitting layer of the third light-emitting device in the third pixel via hole.

6. The manufacturing method according to claim 5, wherein after the reusing the third mask plate to sequentially vapor-deposit the anode film layer and the light-emitting layer of the third light-emitting device in the third pixel via hole, the forming a plurality of light-emitting devices on a side of the glass substrate further comprises:
vapor-depositing cathode film layer material on the light-emitting layer; wherein the cathode film layer material covers the light-emitting layers and the glass substrate, and the cathode film layer material is deposited in the cathode via holes; and
forming patterns of the cathode film layer and the cathode conductive portion on the cathode film layer material through a fifth mask plate, and etching the patterns to obtain the cathode film layer and the cathode conductive portion.

7. The manufacturing method according to claim 3, wherein the defining pixel via holes and cathode via holes on the glass substrate comprises:
performing exposure and development through the first mask plate to form a pattern of the first pixel via hole;
performing exposure and development through the second mask plate to form a pattern of the second pixel via hole;
performing exposure and development through the third mask plate to form a pattern of the third pixel via hole;
performing exposure and development through the fourth mask plate to form a pattern of the cathode via hole;
etching based on the pattern of the first pixel via hole, the pattern of the second pixel via hole, the pattern of the third pixel via hole, and the pattern of the cathode via hole to define the first pixel via hole, the second pixel via hole, the third pixel via hole, and the cathode via hole.

8. The manufacturing method according to claim 2, wherein in an axial direction of the display panel, a height of each connecting portion is greater than a height of a corresponding circuit via hole, a height of the anode conductive portion is less than a height of a corresponding pixel via hole, and a height of the cathode conductive portion is less than a height of a corresponding cathode via hole; in a case where corresponding connecting portions are connected to the anode conductive portion and the cathode conductive portion, the corresponding connecting portions extend into the corresponding pixel via hole and the corresponding cathode via hole.

9. A display panel, comprising:
a drive circuit backplate, comprising a drive circuit layer; and
a light-emitting unit carrier plate, comprising:
a glass substrate, defining pixel via holes and cathode via holes; wherein the cathode via holes are located outside the pixel via holes in a radial direction of the display panel; and
a plurality of light-emitting devices, disposed on a side of the glass substrate; wherein each of the plurality of light-emitting devices comprises an anode film layer, a light-emitting layer, and a cathode film layer formed sequentially from a side near the drive circuit backplate toward a side far from the drive circuit backplate; the anode film layer, the light-emitting layer, and the cathode film layer are disposed in a corresponding pixel via hole; on a side of the glass substrate away from the drive circuit backplate, the cathode film layer extends out of the corresponding pixel via hole and covers the glass substrate; each of the plurality of light-emitting devices further comprises an anode conductive portion and a cathode conductive portion; the anode conductive portion is electrically connected to the anode film layer and extends toward the drive circuit layer; the cathode conductive portion is electrically connected to the cathode film layer, and the cathode conductive portion is disposed in a corresponding cathode via hole and extends toward the drive circuit layer;
wherein in a case where the light-emitting unit substrate is connected to the drive circuit backplate, the glass substrate is disposed on the drive circuit backplate, the anode conductive portion of each light-emitting device is connected to a corresponding portion of the drive circuit layer, and the cathode conductive portion of each light-emitting device is connected to another corresponding portion of the drive circuit layer.

10. The display panel according to claim 9, wherein the drive circuit backplate further comprises:
a drive substrate; wherein the drive circuit layer is disposed on the drive substrate; connecting portions are arranged protruding from a side of the drive circuit layer away from the drive substrate; and
an inorganic layer, disposed on the drive circuit layer, for encapsulating the drive circuit layer on the drive substrate; wherein the inorganic layer defines circuit via holes, and the connecting portions extend into the circuit via holes.

11. The display panel according to claim 9, wherein the pixel via holes comprise a first pixel via hole, a second pixel via hole, and a third pixel via hole; the first pixel via hole is defined by performing laser drilling on the glass substrate through a first mask plate; the second pixel via hole is defined by performing laser drilling on the glass substrate through a second mask plate; the third pixel via hole is defined by performing laser drilling on the glass substrate through a third mask plate; the cathode via hole is defined by performing laser drilling on the glass substrate through a fourth mask plate.

12. The display panel according to claim 11, wherein the light-emitting devices comprise a first light-emitting device, a second light-emitting device, and a third light-emitting device of different colors;
the anode film layer and the light-emitting layer of the first light-emitting device are prepared by sequential vapor-deposition in the first pixel via hole by reusing the first mask plate;
the anode film layer and the light-emitting layer of the second light-emitting device are prepared by sequential vapor-deposition in the second pixel via hole by reusing the second mask plate;
the anode film layer and the light-emitting layer of the third light-emitting device are prepared by sequential vapor-deposition in the third pixel via hole by reusing the third mask plate.

13. The display panel according to claim 11, wherein the pixel via holes and cathode via holes on the glass substrate are prepared by:
performing exposure and development through the first mask plate to form a pattern of the first pixel via hole;
performing exposure and development through the second mask plate to form a pattern of the second pixel via hole;
performing exposure and development through the third mask plate to form a pattern of the third pixel via hole;
performing exposure and development through the fourth mask plate to form a pattern of the cathode via hole;
etching based on the pattern of the first pixel via hole, the pattern of the second pixel via hole, the pattern of the third pixel via hole, and the pattern of the cathode via hole to define the first pixel via hole, the second pixel via hole, the third pixel via hole, and the cathode via hole.

14. The display panel according to claim 9, wherein the cathode film layer and the cathode conductive portion are prepared by:
vapor-depositing cathode film layer material on the light-emitting layer; wherein the cathode film layer material covers the light-emitting layers and the glass substrate, and the cathode film layer material is deposited in the cathode via holes;
forming patterns of the cathode film layer and the cathode conductive portion on the cathode film layer material through a fifth mask plate; and
etching the patterns.

15. The display panel according to claim 10, wherein in an axial direction of the display panel, a height of each connecting portion is greater than a height of a corresponding circuit via hole, a height of the anode conductive portion is less than a height of a corresponding pixel via hole, and a height of the cathode conductive portion is less than a height of a corresponding cathode via hole; in a case where corresponding connecting portions are connected to the anode conductive portion and the cathode conductive portion, the corresponding connecting portions extend into the corresponding pixel via hole and the corresponding cathode via hole.

16. A display panel, manufactured by:
preparing a drive circuit backplate; wherein the drive circuit backplate comprises a drive circuit layer;
preparing a light-emitting unit substrate, comprising:
defining pixel via holes and cathode via holes on the glass substrate, with the cathode via holes located outside the pixel via holes in a radial direction of the display panel; and
forming a plurality of light-emitting devices on a side of the glass substrate; wherein each of the plurality of light-emitting devices comprises an anode film layer, a light-emitting layer, and a cathode film layer formed sequentially from a side near the drive circuit backplate toward a side far from the drive circuit backplate; the anode film layer, the light-emitting layer, and the cathode film layer are disposed in a corresponding pixel via hole; on a side of the glass substrate away from the drive circuit backplate, the cathode film layer extends out of the corresponding pixel via hole and covers the glass substrate; each of the plurality of light-emitting devices further comprises an anode conductive portion and a cathode conductive portion; the anode conductive portion is electrically connected to the anode film layer and extends toward the drive circuit layer; the cathode conductive portion is electrically connected to the cathode film layer, and the cathode conductive portion is disposed in a corresponding cathode via hole and extends toward the drive circuit layer; and
connecting the light-emitting unit substrate to the drive circuit backplate, with the glass substrate disposed on the drive circuit backplate, the anode conductive portion of each light-emitting device connected to a corresponding portion of the drive circuit layer, and the cathode conductive portion of each light-emitting device connected to another corresponding portion of the drive circuit layer.

17. The display panel according to claim 16, wherein the preparing a drive circuit backplate comprises:
forming the drive circuit layer on a drive substrate, and arranging connecting portions protruding from a side of the drive circuit layer away from the drive substrate; and
forming an inorganic layer on the drive circuit layer to encapsulate the drive circuit layer on the drive substrate; wherein the inorganic layer comprises circuit via holes, with the connecting portions extending into the circuit via holes.

18. The display panel according to claim 16, wherein the pixel via holes comprise a first pixel via hole, a second pixel via hole, and a third pixel via hole; the first pixel via hole, the second pixel via hole, and the third pixel via hole are configured to accommodate corresponding light-emitting devices of different colors, and the cathode via hole is configured to accommodate the cathode conductive portion of a corresponding light-emitting device;
wherein the defining pixel via holes and cathode via holes on the glass substrate comprises:
performing laser drilling on the glass substrate through a first mask plate to define the first pixel via hole, performing laser drilling on the glass substrate through a second mask plate to define the second pixel via hole, performing laser drilling on the glass substrate through a third mask plate to define the third pixel via hole, and performing laser drilling on the glass substrate through a fourth mask plate to define the cathode via hole.

19. The display panel according to claim 18, wherein the light-emitting devices comprise a first light-emitting device, a second light-emitting device, and a third light-emitting device of different colors;
the forming a plurality of light-emitting devices on a side of the glass substrate comprises:
reusing the first mask plate to sequentially vapor-deposit the anode film layer and the light-emitting layer of the first light-emitting device in the first pixel via hole;
reusing the second mask plate to sequentially vapor-deposit the anode film layer and the light-emitting layer of the second light-emitting device in the second pixel via hole; and
reusing the third mask plate to sequentially vapor-deposit the anode film layer and the light-emitting layer of the third light-emitting device in the third pixel via hole.

20. The display panel according to claim 19, wherein after the reusing the third mask plate to sequentially vapor-deposit the anode film layer and the light-emitting layer of the third light-emitting device in the third pixel via hole, the forming a plurality of light-emitting devices on a side of the glass substrate further comprises:
vapor-depositing cathode film layer material on the light-emitting layer; wherein the cathode film layer material covers the light-emitting layers and the glass substrate, and the cathode film layer material is deposited in the cathode via holes; and
forming patterns of the cathode film layer and the cathode conductive portion on the cathode film layer material through a fifth mask plate, and etching the patterns to obtain the cathode film layer and the cathode conductive portion.
